(19) United States
(12) Patent Application Publication
(10) Pub. No.: US 2009/0280621 A1
(43) Pub. Date: Nov. 12, 2009

(54) Method Of Producing Bonded Wafer

(75) Inventors: Akihiko Endo, Tokyo (JP); Nishihata Hideki, Tokyo (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sumco Corporation, Tokyo (JP)

(21) Appl. No.: 12/436,728

(22) Filed: May 6, 2009

(30) Foreign Application Priority Data
May 8, 2008 (JP) 2008-122049

(51) Int. Cl. H01L 21/762

(52) U.S. Cl. 438/458; 438/459; 257/E21.568

(57) ABSTRACT

In a method of producing a bonded wafer, a volume fraction of SiO₂ particles dispersed into silicon in an oxygen ion implanted layer formed at a step of implanting oxygen ions into a wafer for active layer and a subsequent heat treatment step is set to not less than 30% but not more than 80%; and at a step of thinning a portion of the wafer for active layer, the oxygen ion implanted layer formed in the above step is used as a polishing stop layer to polish at least the portion of the wafer for active layer.

### CROSS REFERENCES TO RELATED APPLICATIONS

This application claims priority to Japanese Patent Application No. 2008-122049, filed May 8, 2008, the disclosure of which is incorporated by reference herein.

### BACKGROUND OF THE INVENTION

1. Field of the Invention

This invention relates to a method of producing a bonded wafer, and more particularly to a method of producing a bonded wafer in which an oxygen ion implanted layer is used effectively as a polishing stop layer.

2. Description of the Related Art

As a typical production method of a bonded wafer, there are known a method wherein a silicon wafer having an oxide film (insulating film) is bonded to another silicon wafer and then one side of the resulting bonded wafer is ground and polished to form SOI (Silicon On Insulator) layer (grinding-polishing method), a method wherein oxygen ions are implanted into an interior of a silicon wafer and thereafter a high-temperature annealing is conducted to form a buried oxide film (BOX) layer in the silicon wafer and then an upper portion of the BOX layer is rendered into SOI layer (SIMOX: Separation by Implanted Oxygen method), and a method wherein ions of hydrogen or the like are implanted into a surface layer portion of a silicon wafer for SOI layer (wafer for active layer) to form an ion implanted layer and thereafter the wafer is bonded to a silicon wafer for support substrate and then the bonded wafer is exfoliated at the ion implanted layer through a heat treatment to form SOI layer (smart cut method). (For SIMOX method, see, e.g., JP-A-H05-291543.)

However, any methods described above have a problem that the thickness uniformity of the active layer is poor (±30% or more).

As a solution for the above problem, the inventors have already developed a process of combining the oxygen ion implanting method with the grinding-polishing method, namely “A method for producing a bonded wafer by directly bonding a wafer for active layer having or not having an insulating film on its surface to a wafer for support layer and then thinning the wafer for active layer, which comprises a time-oriented combination of:

a step of implanting oxygen ions into the wafer for active layer to form an oxygen ion implanted layer in the active layer;

a step of subjecting the wafer for active layer to a heat treatment at a temperature of not lower than 1110° C. in a non-oxidizing atmosphere;

a step of bonding the wafer for active layer to a wafer for support layer;

a step of heat-treating for improving a bonding strength of the bonded wafer;

a step of grinding a portion of the wafer for active layer in the bonded wafer short of the oxygen ion implanted layer;

a step of further polishing or etching the wafer for active layer to expose the oxygen ion implanted layer;

a step of oxidizing the bonded wafer to form an oxide film on the exposed surface of the oxygen ion implanted layer;

a step of removing the oxide film; and
a step of heat-treating at a temperature of not higher than 1100° C. in a non-oxidizing atmosphere to planarize the wafer for active layer in the bonded wafer.”, which has been disclosed (see JP-A-2008-16534). According to this method, it is made possible to provide a directly bonded wafer being relatively excellent in the thickness uniformity of the active layer and relatively less in the defects as evaluated by a transmission electron microscope (TEM).

In the method disclosed in JP-A-2008-16534, however, the oxygen ion implanted layer is disclosed to serve as a polishing stop layer, but the conditions for the oxygen ion implanted layer desirable as a polishing stop layer are not disclosed, so that there is a problem that the resulting oxygen ion implanted layer is not necessarily optimized as a polishing stop layer.

That is, the oxygen ion implanted layer formed in the above method may have a double layer structure consisting of a layer A near to a surface of a portion of the wafer for active layer (boundary between BOX layer and SOI layer in FIG. 6) located at the side of the oxygen ion implantation (lower side in FIG. 6) and a layer B apart from the surface located at the side of the oxygen ion implantation as shown by a TEM photograph at section in FIG. 2(b) and schematically shown in FIGS. 6(a)-(c). In case of such a double layer structure, the volume fraction of SiO₂ particles dispersed into silicon of the oxygen ion implanted layer becomes lower, and hence SiO₂ particles are dropped off from the oxygen ion implanted layer during the polishing from the side of the layer B, and after the stop of the polishing, the irregularity is apt to be easily left on the surface of the oxygen ion implanted layer as shown in FIG. 6(a).

In the subsequent oxidation treatment, therefore, as shown in FIG. 6(b), an oxide film C oxidized to a given depth including the oxygen ion implanted layer digs into the surface of the SOI layer depending on the surface irregularity of the oxygen ion implanted layer, and hence the irregularity is apt to be left on the surface of the SOI layer after the removal of the oxide film C as shown in FIG. 6(c). In the above method, therefore, the surface of the wafer for active layer is planarized in the subsequent heat treatment step to obtain a thickness uniformity of the active layer, but there is a problem to be solved that the heat treatment takes more time and man-hours.

### SUMMARY OF THE INVENTION

It is, therefore, an object of the invention to advantageously solve the above problem and to provide a method of advantageously producing a bonded wafer wherein an oxygen ion implanted layer is obtained to have a sufficiently high polishing stop function desirable as a polishing stop layer.

The inventors have made various studies on polishing stop conditions with an oxygen ion implanted layer in order to solve the above problem, and found that the oxygen ion implanted layer desirable as a polishing stop layer has a volume fraction of SiO₂ particles dispersed into silicon within a given range. The invention is based on the above knowledge.

That is, the summary and construction of the invention are as follows.

1. A method of producing a bonded wafer by bonding a wafer for active layer to a wafer for support layer, which comprises a series of steps including:

(1) a step of implanting oxygen ions into the wafer for active layer to form an oxygen ion implanted layer;

(2) a step of bonding the oxygen ion implanted surface of the wafer for active layer to the wafer for support layer directly or through an insulating film;

(3) a step of conducting a heat treatment for increasing a bonding strength of the bonded wafer,

(4) a step of thinning a portion of the wafer for active layer in the bonded wafer to expose the oxygen ion implanted layer; and

(5) a step of removing the oxygen ion implanted layer from the wafer for active layer in the bonded wafer, wherein

a volume fraction of SiO₂ particles dispersed into silicon in the oxygen ion implanted layer formed at the step (1) of implanting oxygen ions into the wafer for active layer or at the above implantation step and subsequent heat treatment step is set to not less than 30% but not more than 80%; and

at the step (4) of thinning the portion of the wafer for active layer, the oxygen ion implanted layer formed in the step (1) of implanting oxygen ions into the wafer for active layer is used as a polishing stop layer to polish at least the portion of the wafer for active layer.

2. A method of producing a bonded wafer according to claim 1, wherein at the step (1) of implanting oxygen ions into the wafer for active layer, oxygen ions are implanted so that a first differential value of average oxygen concentration distribution directing from the implanted surface side in oxygen ion implanted layer toward an inside thereof is positive.

3. A method of producing a bonded wafer according to claim 1 or 2, wherein the step (5) of removing the oxygen ion implanted layer is further followed by (6) a step of planarizing and/or thinning the surface of the wafer for active layer in the bonded wafer.

When the volume fraction of SiO₂ particles dispersed into silicon in the oxygen ion implanted layer is less than 30%, SiO₂ particles are too separated from each other, so that SiO₂ particles are easily dropped off during the polishing for thinning the wafer for active layer and hence the polishing stop function is not sufficiently high. That is, the irregularity is apt to be easily left on the surface of the oxygen ion implanted layer after the polishing stop.

While, when the volume fraction of SiO₂ particles dispersed into silicon in the oxygen ion implanted layer exceeds 80%, SiO₂ particles are hardly dropped off during the polishing for thinning the wafer for active layer and hence the polishing stop function is sufficiently high, but the higher temperature and higher oxygen concentration are required in the implantation of oxygen ions and the cost becomes higher in the oxygen ion implantation.

According to the invention in which the volume fraction of SiO₂ particles is not less than 30% but not more than 80%, therefore, the oxygen ion implanted layer having a sufficiently high polishing stop function desirable as a polishing stop layer and capable of implanting oxygen ions cheaply can be obtained during the production of the bonded wafer, so that it is possible to produce a bonded wafer being excellent in the thickness uniformity of the active layer at low cost.

Also, when oxygen ions are implanted at the step of implanting oxygen ions into the wafer for active layer so that the first differential value of average oxygen concentration distribution directing from the implanted surface side in the oxygen ion implanted layer toward the inside thereof is positive or a single peak, the oxygen ion implanted layer has such a single layer structure that the oxygen concentration becomes higher from the implanted surface side toward the inside, so that it is possible to stably obtain a sufficiently high polishing stop function.

Moreover, it is possible to produce a bonded wafer being more excellent in the thickness uniformity of the active layer when the step of planarizing and/or thinning the surface of the wafer for active layer in the bonded wafer is further conducted after the step of removing the oxygen ion implanted layer.

### BRIEF DESCRIPTION OF THE DRAWINGS

The invention will be described with reference to the accompanying drawings, wherein:

FIG. 1 is a flow chart of production steps according to one embodiment of the invention;

FIG. 2(a) is a TEM photograph at section of a wafer subjected to a heat treatment after an oxygen ion implantation under conditions of the above embodiment;

FIG. 2(b) is a TEM photograph at section of a wafer subjected to a heat treatment after an oxygen ion implantation under conventional conditions;

FIG. 3(a) is a diagram showing a relation between depth and average oxygen concentration of a bonded wafer in Example and Comparative Example based on the above embodiment;

FIG. 3(b) is an explanatory diagram showing implantation conditions and polishing stop results in these Example and Comparative Example;

FIG. 4(a) is a photograph showing an EELS analyzed result of a structure of an oxygen ion implanted layer in a bonded wafer of the above Example;

FIG. 4(b) is a photograph showing a spectrum image of Si in the framed area of FIG. 4(a);

FIG. 4(c) is a photograph showing a spectrum image of O in the framed area of FIG. 4(a);

FIG. 5(a) is a photograph showing an EELS analyzed result of a structure of an oxygen ion implanted layer in a bonded wafer of the above Example as to the same area as in FIG. 4(a);

FIG. 5(b) is a diagram showing spectrums for three points P1, P2 and P3 in this order from a surface side within the framed area of FIG. 5(a);

FIG. 5(c) is a diagram showing a typical spectrum image of Si in a textbook;

FIG. 5(d) is a diagram showing a typical spectrum image of SiO₂ in a textbook;

FIGS. 6(a)-(c) are schematically cross sectional views showing an influence of a polished surface state after the polishing stop of a bonded wafer subjected to oxygen ion implantation and heat treatment before the bonding according to the conventional method upon a surface state after the removal of an oxide film, respectively.

### DESCRIPTION OF THE PREFERRED EMBODIMENTS

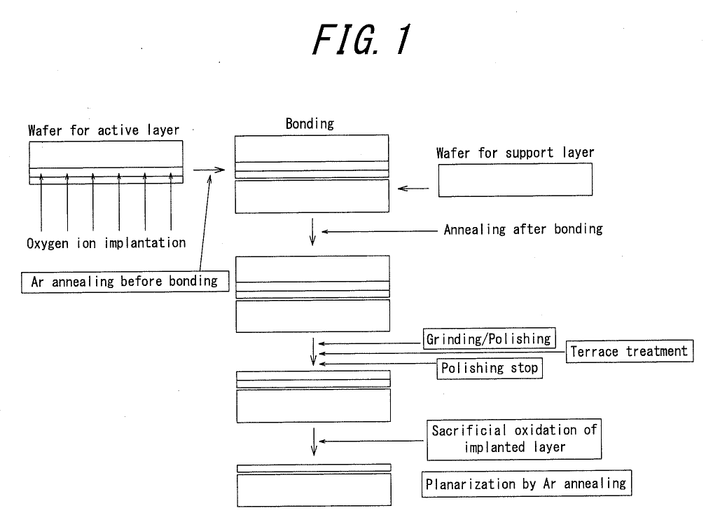

An embodiment of the invention will be concretely described below. At first, the invention will be concretely explained with respect to a bonded wafer to be targeted in this embodiment and each production step of the embodiment according to a flow chart shown in FIG. 1.

### Bonded Wafer

In the production of a bonded wafer such as a SIMOX wafer or the like, two silicon wafers, i.e. a wafer for active layer and a wafer for support layer are bonded to each other. This embodiment is applicable to not only a case that the bonding of both wafers is conducted through an insulating film (oxide film) but also a case that both the wafers are directly bonded without such an insulating film.

Moreover, a kind and a concentration of a dopant, an oxygen concentration and the like are not limited as long as the wafer to be bonded has a good surface roughness suitable for bonding. In order to further reduce defects, however, it is preferable to use a wafer having no COP (Crystal Oriented Particle) or a less COP. For the reduction of COP may be applied a method of optimizing CZ drawing conditions to reduce COP, a method of subjecting a wafer to a high-temperature heat treatment of not lower than 1000° C. in a reducing atmosphere after mirror working, a method of epitaxial-growing Si on a wafer by CVD or the like, and so on.

(1) Step of Implanting Oxygen Ions into a Wafer for Active Layer

In this embodiment, oxygen ions are first implanted into a wafer for active layer.

In this case, the acceleration voltage in oxygen ion implantation may be properly selected depending on the thickness of the active layer in the final product and is not particularly limited. Therefore, the oxygen ion implantation may be carried out at an acceleration voltage of about 100 to 300 keV for a usual oxygen ion implanter.

On the other hand, the dose of oxygen ions in the implantation is set so that the volume fraction of SiO₂ particles dispersed into silicon in the oxygen ion implanted layer is not less than 30% but not more than 80% through the combination with the subsequent step. When the dose of oxygen ions is small, it is preferable to conduct a preliminary heat treatment before the bonding step.

That is, the dose of oxygen ions in the implantation is within a range of 5×10¹⁷ to 1×10¹⁸ atoms/cm² when the heat treatment step is not conducted before the bonding, while when the preliminary heat treatment is carried out before the bonding step, the dose is 1×10¹⁷ to 8×10¹⁷ atoms/cm² at a heat-treating temperature of 1100° C., 0.8×10¹⁷ to 4×10¹⁷ atoms/cm² at a heat-treating temperature of 1200° C., and 0.5×10¹⁷ to 2×10¹⁷ atoms/cm² at a heat-treating temperature of 1350° C.

When the dose of oxygen ions in the implantation is less than 5×10¹⁷ atoms/cm² without the heat treatment, or less than 1×10¹⁷ atoms/cm² at the heat-treating temperature of 1100° C., or less than 0.8×10¹⁷ atoms/cm² at the heat-treating temperature of 1200° C., or less than 0.5×10¹⁷ atoms/cm² at the heat-treating temperature of 1350° C., the volume fraction of SiO₂ particles dispersed into silicon in the oxygen ion implanted layer without the heat treatment or after the heat treatment is less than 30%, and hence an Si crystal layer or an Si amorphous layer containing oxygen atoms takes an obvious double layer structure instead of a single layer or is not formed sufficiently, and also SiO₂ particles are too apart from each other, so that when the polishing is conducted for thinning the wafer for active layer at the step (5) after the bonding as mentioned later, SiO₂ particles are easily dropped off, and hence the polishing stop cannot be conducted accurately.

On the other hand, when the dose of oxygen ions in the implantation exceeds 1×10¹⁸ atoms/cm² without the heat treatment, or exceeds 8×10¹⁸ atoms/cm² at the heat-treating temperature of 1100° C., or exceeds 4×10¹⁸ atoms/cm² at the heat-treating temperature of 1200° C., or exceeds 2×10¹⁸ atoms/cm² at the heat-treating temperature of 1350° C., the volume fraction of SiO₂ particles dispersed into silicon in the oxygen ion implanted layer without the heat treatment or after the heat treatment exceeds 80%, and hence the polishing stop can be conducted accurately at the step (5) after the bonding, but higher temperature and higher oxygen concentration are required in the oxygen ion implantation and the cost runs up for the oxygen ion implantation.

In the oxygen ion implantation, the substrate temperature is required to be not higher than 200° C. When the temperature exceeds 200° C., an amorphous layer is not formed sufficiently. Preferably, the substrate temperature is not lower than room temperature (about 20° C.) but not higher than 100° C. Moreover, it is possible to conduct the oxygen ion implantation at a temperature of not higher than room temperature, but it is required to add a mechanism for forcedly cooling the wafer to the implanter.

Moreover, the oxygen ion implantation may be divided into plural times. In this case, oxygen ions are first implanted at a higher temperature and then implanted at a lower temperature (for example, not lower than room temperatures but not higher than 100° C.) up to a depth contacting with the high-temperature implanted layer. Preferably, this facilitates the formation of a single layer after the heat treatment.

Also, the cleaning may be conducted between divided implantation stages. As the cleaning means, it is preferable to use SC1, HF, O₃, an organic acid and the like, which are excellent in the ability for removing the particles.

(2) Step of Subjecting Wafer for Active Layer to Heat Treatment

Although the cleaning and bonding may be conducted after the oxygen ion implantation, the wafer for active layer is subjected to a heat treatment before the bonding, whereby the dose of oxygen ions implanted can be reduced to lower costs. When the heat treatment is conducted after the oxygen ion implantation in this embodiment, the wafer is heat-treated at not lower than 1000° C. for not less than 5 hours, preferably at 1100° C. for not less than 1 hour, more preferably at not lower than 1200° C. but not higher than 1350° C. for not less than 10 minutes before the bonding. If the heat treatment at a temperature of lower than 1000° C. is conducted for a long time of not less than 5 hours, the oxygen ion implanted layer takes an obvious double layer structure, or SiO2 phase state is not sufficiently formed by reacting the implanted oxygen ions with Si, so that the polishing stop function becomes not sufficiently high.

When the heat treatment is conducted in a non-oxidizing atmosphere, oxygen implanted in the vicinity of an outermost surface during the oxygen ion implantation is diffused outward to reduce oxygen concentration, which contributes to suppress oxygen precipitates in the vicinity of the outermost surface in a heat treatment for increasing the bonding strength. As a result, it is possible to further reduce defect density. As the non-oxidizing atmosphere is advantageously adapted Ar, H₂ or a mixed atmosphere thereof.

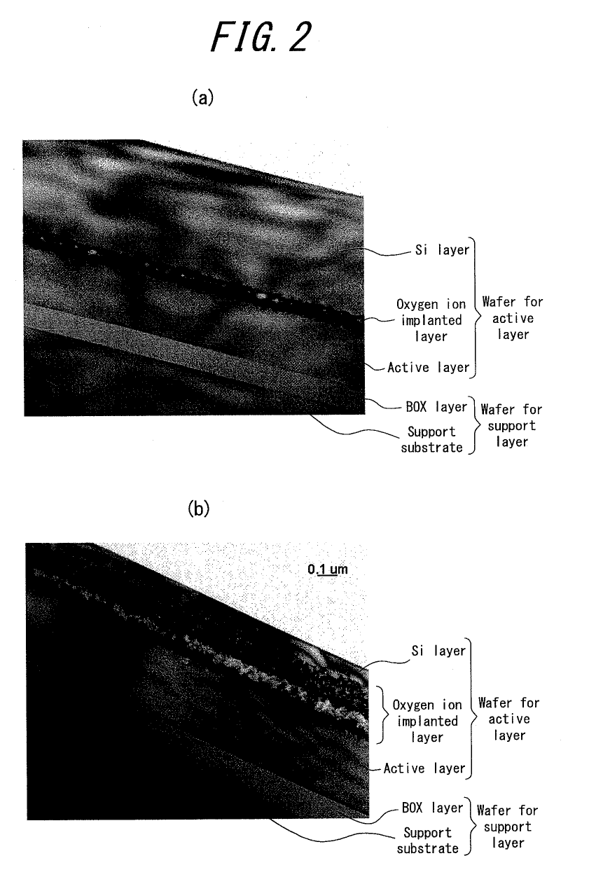

In FIGS. 2(a) and 2(b) are shown TEM photographs at section of two bonded wafers each formed by implanting oxygen ions into a wafer for active layer under conditions for the above embodiment or conventional conditions, subjecting the wafer to a heat treatment, bonding with a wafer for support layer and then subjecting the resulting bonded wafer to a heat treatment for improving the bonding strength at 1100° C. for 1 hour, respectively. Moreover, the wafer for support layer is subjected to a thermal oxidization to form a BOX layer having a thickness of 0.2 μm.

At this moment, conditions for oxygen ion implantation and conditions for heat treatment are as follows.

Conditions in conventional technique:
For oxygen ion implantation treatment

Acceleration voltage: 200 keV, dose: 1×10¹⁷ atoms/cm², substrate temperature: 400° C.+dose: 5×10¹⁵ atoms/cm², substrate temperature: 100° C.

For heat treatment: 1100° C., 0.5 hour

### Condition of the Invention

For oxygen ion implantation treatment

Acceleration voltage: 200 keV, dose: 1×10¹⁷ atoms/cm², substrate temperature: 400° C.+dose: 5×10¹⁵ atoms/cm², substrate temperature: 100° C.

For heat treatment: 1200° C., 2 hours

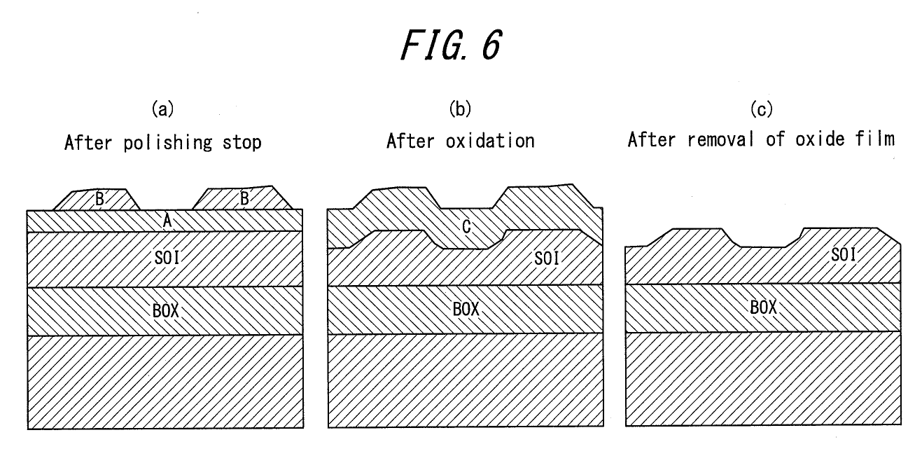

As seen from the photographs, the oxygen ion implanted layer (SiO₂ layer) under the conventional conditions is observed as a double layer structure consisting of an area where SiO₂ particles are relatively continuous and look white (corresponding to A area in FIG. 6 and being high in the polishing stop ability) and an area where SiO₂ particles are dispersed and look black (corresponding to B area in FIG. 6 and being low in the polishing stop ability). In case of polishing at this state, it is basically possible to stop the polishing somewhere on a polishing stop layer (oxygen ion implanted area). In the B area being low in the polishing stop ability, however, an area partially passing through the B area and stopping at the A area being high in the polishing stop ability is formed by in-plane distribution of the polishing. Therefore, as shown in FIGS. 6(a)-(c), the formation of irregularity can not be avoided in the surface of the active layer after Si layer is polished after the bonding and an oxide film is formed and then removed.

On the contrary, it is understood under the conditions of the invention that an oxygen ion implanted layer having a sufficiently high polishing stop function desirable as a polishing stop layer and capable of implanting oxygen ions cheaply is formed because an interface between the oxygen ion implanted layer (SiO₂ layer) and surface Si layer is smooth.

(3) Step of Bonding Wafer for Active Layer to Wafer for Support Layer

Then, the wafer for active layer is bonded to the wafer for support layer. In this case, both the wafers may be bonded to each other through an insulating film or directly without the insulating film.

When the bonding is conducted with the insulating film, it is preferable to use an oxide film (SiO₂) such as BOX, a nitride film (Si₃N₄) or the like as the insulating film. As a method of forming the film are preferable a heat treatment in an oxidizing atmosphere or a nitrogen atmosphere (thermal oxidation, thermal nitriding), CVD and so on. As the thermal oxidation, wet oxidation using steam can be used in addition to the use of oxygen gas.

Furthermore, the insulating film may be formed before or after the oxygen ion implantation. When the insulating film is formed before the implantation, a higher acceleration voltage is required in the oxygen ion implantation for producing an SOI substrate having a large thickness of SOI layer. In a general-purpose ion implanter, the acceleration voltage is typically not more than 200 keV, so that when the thickness of SOI layer is 50 to 200 nm, the thickness of BOX layer is not more than 200 nm, preferably not more than 50 nm, more preferably not more than 20 nm considering a process margin. On the other hand, when the insulating film is formed after the implantation, it is necessary to form the film at a temperature of not higher than 1000° C. where amorphous crystallization hardly progresses.

The formation of such an insulating film can be carried out on either the wafer for active layer or the wafer for support layer or both.

Further, it is advantageous to conduct the cleaning treatment before the bonding for suppressing the occurrence of voids due to particles.

As the cleaning means, it is effective to use a general method for cleaning silicon wafers with SC1+SC2, HF+O₃, an organic acid or a combination thereof.

Furthermore, it is advantageous to contact two wafers with each other at a pressure lower than atmospheric pressure in the bonding since the occurrence of voids due to the wafer form can be suppressed. A preferable pressure is not higher than 0.5 atmosphere, more preferably 0.2 atmosphere.

In addition, when a peeling risk is feared depending on conditions (pressure, speed) of grinding/polishing after the bonding, it is advantageous that the surface of silicon wafer before the bonding is subjected to activation treatment with plasma using oxygen, nitrogen, He, H₂, Ar or a mixed atmosphere thereof for increasing the bonding strength.

In case of the direct bonding, H₂O adsorbed on the surface to be bonded is changed into SiO₂ through the subsequent heat treatment to be found on the bonded interface, so that the formation of SiO₂ may be suppressed by cleaning the faces to be bonded with HF and then bonding them at their hydrophobic faces with each other. Thus, the oxide can be reduced at the bonded interface to bring about the improvement of device properties.

(4) Step of Heat-Treating for Improving Bonding Strength

Next, the heat treatment is conducted for improving the bonding strength. This heat treatment is conducted at a temperature of not lower than 1000° C. for sufficiently increasing the bonding strength, preferably at a temperature of not lower than 1100° C., more preferably at a temperature of not more than 1100° C. for not less than 2 hours. The atmosphere is not particularly limited, but an oxidizing atmosphere is preferable for forming an oxide film with a thickness of not less than 150 nm so as to protect the rear face of the wafer at the subsequent grinding step.

(5) Step of Thinning Wafer for Active Layer to Expose Oxygen Ion Implanted Layer

Subsequently, the wafer for active layer is thinned by grinding and polishing to expose the oxygen ion implanted layer.

### Grinding

The wafer for active layer in the bonded wafer is conducted by a mechanical grinding. By this grinding is left a part of the wafer for active layer on the surface side of the oxygen ion implanted layer. The thickness of the part of the wafer for active layer to be left is not particularly limited.

It is preferable to conduct the grinding just before the oxygen ion implanted layer in order to shorten the time of the subsequent polishing step. However, considering the precision of the grinding device and the damage depth through the grinding (about 2 μm), the thickness of residual Si layer is preferable to be about 3 to 10 μm.

### Polishing

Following to the grinding, the wafer for active layer in the bonded wafer is polished to expose the oxygen ion implanted layer.

In this polishing method, it is preferable to conduct the polishing while feeding a polishing solution having an abrasive concentration of not more than 1 mass %. As the polishing solution is mentioned an alkaline solution having an abrasive (e.g. silica) concentration of not more than 1 mass %. Moreover, as the alkaline solution is preferable an inorganic alkali solution (KOH, NaOH or the like), an organic alkali solution (for example, piperazine composed mainly of amine, ethylene diamine or the like), or a mixed solution thereof.

In the grinding process, since the abrasive concentration is not more than 1 mass %, the mechanical polishing action with the abrasives is hardly caused, and the chemical polishing action is preferential. Thus, a part (Si layer) of the wafer for active layer is polished by the chemical polishing action with the alkaline solution. Since the alkaline solution is high in the etching rate ratio of Si/SiO₂, the Si layer as a part of the wafer for active layer can be polished efficiently, whereas the layer containing more than a certain volume of SiO₂ particles is hardly polished. Even if the mechanical accuracy of the polishing device is insufficient, only the Si layer is polished without substantially polishing the oxygen ion implanted layer, so that the oxygen ion implanted layer can be exposed uniformly.

Therefore, the oxygen ion implanted layer of the embodiment serves as a polishing stop layer having a sufficiently high polishing stop function.

By etching Si before the polishing is particularly smoothened a boundary between a terrace (an outermost peripheral region of 1 to 3 mm not bonding two wafers to each other) and the bonded region, whereby the occurrence of particles is suppressed. Moreover, only the terrace may be ground before the polishing.

(6) Step of Removing Oxygen Ion Implanted Layer

In this embodiment is removed the exposed oxygen ion implanted layer. The oxygen ion implanted layer is comprised of amorphous Si containing oxygen atoms, and partially recrystallized Si and SiO₂. As the removing method are applicable an etching process, an oxidation+etching process, a polishing process and the like.

### Etching Process

Since the insufficient conditions on the dose of oxygen ions and the heat treatment are selected in order that the oxygen ion implanted layer forms a complete SiO₂ layer (BOX layer), it is preferable to conduct etching with HF solution removing SiO₂ or alternative etching with an alkali solution removing Si or a SC1 solution or ozon solution oxidizing Si and HF solution removing SiO₂ formed by oxidation.

In any case, the HF solution is used, so that it is preferable to repeatedly conduct the oxidation+HF until the surface of the wafer as a whole is changed into a water-repellent surface as a goal for the removal of SiO₂ after the immersion in the HF solution.

### Oxidation Process

This process comprises a step of forming an oxide film of a given thickness on the exposed surface of the oxygen ion implanted layer and a step of removing the resulting oxide film.

Since it is enough to conduct the oxidation in an oxidizing atmosphere, the treating temperature is not particularly limited, but is preferable to be 600 to 1100° C. in the oxidizing atmosphere. When the temperature is lower than 600° C., the oxidation reaction does not proceed, and hence the oxide film cannot be removed with HF solution. While, when it exceeds 1000° C., crystal defects introduced by the oxygen ion implantation extends into the SOI layer, and as a result, the crystal defects increase.

When the oxidation is conducted at a lower temperature, a wet oxidation using H₂O vapor or a hydrochloric acid oxidation with an oxidizing gas including HCl gas may be applied for increasing a growing rate of the oxide film, which is more preferable for obtaining a high throughput.

The thickness of the oxide film is not particularly limited, but it is preferable to be larger than a thickness of a crystal defect layer if the crystal defect layer is existent in the oxygen ion implanted layer, and is particularly preferable to be about 100 to 500 nm under the conditions of oxygen ion implantation according to the embodiment. When the thickness of the oxide film is less than 100 nm, Si crystal layer or Si amorphous layer containing SiO₂ cannot be sufficiently removed under the conditions of oxygen ion implantation according to the embodiment, while when it exceeds 500 nm, the thickness uniformity of the active layer is deteriorated due to the breakage of the in-plane thickness uniformity in the oxide film.

The removal of the oxide film may be conducted by cleaning with HF solution or by etching through annealing with hydrogen gas or Ar gas or a gas containing HF. At this moment, the above oxidation treatment and removal treatment may be conducted plural times. Thus, it is possible to conduct further thinning of the active layer while maintaining the planarized surface roughness.

After the removal of the oxide film, it is advantageous to remove the particles and metallic impurity attached to the surface of the bonded wafer, for example, by immersing the bonded wafer in a mixed solution of an organic acid and hydrofluoric acid.

(7) Step of Planarizing and/or Thinning Surface of Wafer for Active Layer

Subsequently, the surface of the wafer for active layer is subjected to planarization and the like. Because the surface of the bonded wafer after the removal of the oxygen ion implanted layer is rough as compared with the mirror polishing so that it is desirable to be planarized.

As the planarization are applicable a heat treatment in a reducing atmosphere, a polishing process, a gas etching with a gas, ion or a radical capable of etching Si, and the like.

### Polishing Process

The surface of the bonded wafer is slightly polished to improve the surface roughness. The polishing margin is preferable to be about 10 to 500 nm. When the margin is less than 10 nm, the surface roughness cannot be sufficiently improved, while when it exceeds 500 nm, the thickness uniformity of the active layer is deteriorated. By this treatment can be rendered the surface roughness (RMS) into not more than 0.5 nm.

### Heat Treatment in Reducing Atmosphere

The surface roughness of the bonded wafer is improved by heat-treating in Ar, H₂ or a mixed atmosphere thereof. The heat treating temperature is preferable to be not lower than 1000° C. but not higher than 1300° C. The heat-treating time is required to take a long time as the temperature becomes lower, and is preferable to be about 1 to 2 hours at 1000 to 1200° C., about 10 to 30 minutes at 1200 to 1250° C. and about 1 to 5 minutes above 1250° C. If the heat treatment is conducted under conditions of higher temperature and longer time exceeding the above values, there is a fear of deteriorating the in-plane thickness uniformity of the active layer due to the etching action of the reducing atmosphere.

When a surface activation using plasma or the like is conducted as a pretreatment for the bonding, the heat treatment at not lower than 1100° C. is not necessarily required.

As a heat-treating furnace are preferable a resistance heating type vertical furnace capable of simultaneously treating plural wafers, a lamp heating type RTA (high-speed temperature rising-descending furnace) treating individual wafers, and so on. Particularly, RTA is effective in the treatment of not lower than 1200° C.

By this heat treatment, the surface roughness (RMS) can be rendered into not more than 0.5 nm likewise the polishing process.

The oxide film generated on the surface by this heat treatment may be removed by cleaning with HF solution or by etching through annealing with a hydrogen gas, Ar gas or a gas containing HF.

Thus, there can be obtained a bonded wafer being excellent in the thickness uniformity and less in the defects and having dramatically improved surface roughness.

### EXAMPLE

There are provided 4 sets of two silicon wafers of 300 mm in diameter sliced from a silicon ingot grown by CZ method and doped with boron, wherein three sets are Examples based on the above embodiment and one set is Comparative Example. One of two silicon wafers in each set is a wafer for active layer and the other is a wafer for support layer.

The wafer for active layer of each set is subjected to a heat treatment in an oxidizing atmosphere at 1000° C. for 3 hours to form an oxide film having a thickness of 150 nm thereon.

Then, oxygen ion implantation is carried out from the surface of the wafer for active layer in each set at an acceleration voltage of 200 keV. In this case, the substrate temperature of each set is 300 to 500° C., and the dose is 1×10¹⁷ atoms/cm² for three sets of Examples and 0.5×10¹⁷ atoms/cm² for one set of Comparative Example, respectively. In order to promote the formation of SiO₂, an amorphous layer is formed by implanting 5×10¹⁵ atoms/cm² of oxygen ions at 200 keV and at a substrate temperature of from room temperature to lower than 200° C.

As a result, an oxygen ion implanted layer is formed at a depth position of about 600 to 800 nm from the surface of the wafer for active layer in each set.

Then, the wafer for active layer in each set is subjected to a heat treatment (annealing) before bonding in a non-oxidizing (Ar) atmosphere, whereby the oxygen ion implanted layer is rendered continuous. How ever, the heat-treating temperature for three sets of Examples is 1100° C., 1200° C. and 1350° C., respectively, and the holding time is for 1 hour, while the heat-treating temperature for one set of Comparative Example is 1100° C. and the holding time is for 1 hour.

Next, both wafers in each set are cleaned with HF and ozone to remove particles from the surface to be bonded and thereafter bonded to each other in each set.

Thereafter, the bonded wafer in each set is subjected to a heat treatment (annealing) after the bonding for strongly bonding the bonding interfaces of both wafers. The heat-treating conditions are 1100° C. in an oxidizing gas atmosphere for 2 hours, and an oxide film having a thickness of about 200 to 400 nm is formed the rear face of the bonded wafer on as a rear face protection film for subsequent processing.

Then, the wafer for active layer in the bonded wafer of each set is ground by a given thickness from the surface thereof by using a grinding apparatus. That is, the grinding treatment is carried out at the surface side of the oxygen ion implanted layer so as to leave a part of the wafer for active layer (corresponding to a thickness of about 5 μm) thereon.

Next, the oxygen ion implanted layer is exposed by polishing the surface of each bonded wafer after the grinding while feeding a polishing agent having an abrasive (silica) concentration of not more than 1 mass %. As the polishing a gent is used an alkaline solution having an abrasive concentration of not more than 1 mass %. The alkaline solution is an organic alkali solution composed mainly of amine (e.g. piperazine, ethylene diamine or the like).

Thereafter, each bonded wafer is subjected to a wet oxidation treatment in an oxidizing atmosphere at a temperature of 950° C. for 0.5 hour. As a result, an oxide film having a given thickness is formed on the exposed surface of the oxygen ion implanted layer, whereby all Si crystal layer or Si amorphous layer containing SiO₂ particles is converted into an oxide film (SiO₂). Next, such an oxide film is removed by HF etching (concentration of HF: 10%, temperature: 20° C.). After the removal of the oxide film, the thickness of the exposed active layer is uniformized and thinned in the surface.

Then, each bonded wafer is cleaned by the following treatment. At first, the bonded wafer is immersed in an aqueous ozone solution having an ozone concentration of 5 ppm, an aqueous solution containing 0.06 mass % of citric acid as an organic acid in pure water, an aqueous solution containing 0.05 mass % of hydrofluoric acid, an aqueous solution containing 0.6 mass % of citric acid as an organic acid in pure water and finally an aqueous ozone solution having an ozone concentration of 5 ppm in this order, respectively. Each of the immersing treatments is conducted at room temperature for 5 minutes. By this cleaning treatment are removed metal impurity and particles from the surface of each bonded wafer.

After the above cleaning, each bonded wafer is subjected to a heat treatment in an argon gas atmosphere at 1100° C. for 2 hour to finish the bonded wafer.

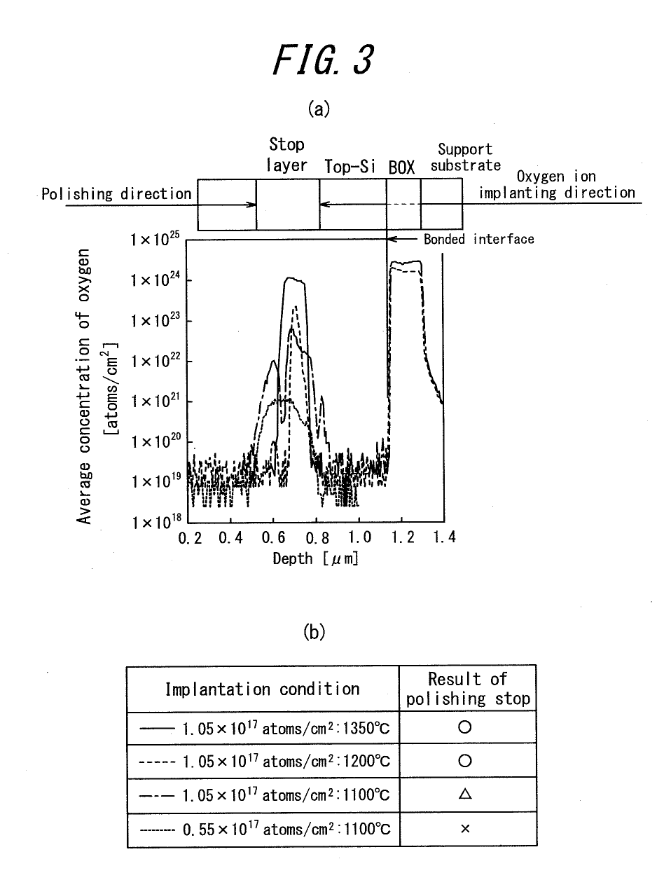

FIGS. 3(a) and 3(b) show results of oxygen distribution in a thickness direction as analyzed by a secondary ion mass spectrometer (SIMS), oxygen ion implantation conditions and results on polishing stop with respect to the bonded wafers of three Examples and one Comparative Example obtained as above. In Examples using the dose of 1.05×10¹⁷ atoms/cm² and the heat-treating temperature before bonding of 1200° C. or 1350° C., the average oxygen concentration in the stop layer (oxygen ion implanted layer) clearly shows a single peak and the first differential value of average oxygen concentration distribution in the oxygen ion implanted layer in a direction inward from the implanted surface side (right end surface of Top-Si layer in the figure) is positive.

In Example using the dose of 1.05×10¹⁷ atoms/cm² and the heat-treating temperature before bonding of 1100° C., the average oxygen concentration in the stop layer (oxygen ion implanted layer) shows two peaks although they are not definite.

In Comparative Example using the dose of 0.55×10¹⁷ atoms/cm² and the heat-treating temperature before bonding of 1100° C., the average oxygen concentration in the stop layer (oxygen ion implanted layer) shows a gentle round peak.

As a result of the investigation on these polishing stop states, two Examples using 1200° C. and 1350° C. show the sufficiently good state, and the third Example using 1100° C. shown a good state as compared with Comparative Example, while the irregularity is observed in Comparative Example using 1100° C.

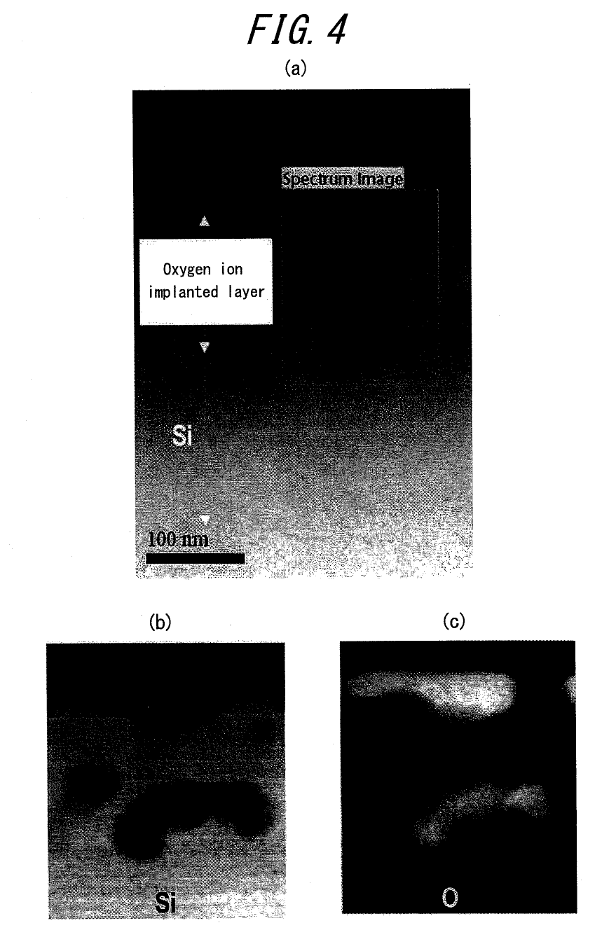

FIG. 4(a) shows a result of analyzing a structure of an oxygen ion implanted layer (stop layer) after polishing stop in the bonded wafer of the above Example by means of an electron energy loss spectroscopy (EELS). FIGS. 4(b) and 4(c) show a spectrum image of Si (white portion and grey portion) and a spectrum image of O (white portion) in a framed area of the oxygen ion implanted layer in FIG. 4(a). In order that an aggregate of SiO₂ particles (not SiOₓ) is existent in the Si matrix after the polishing stop, the volume fraction of the average oxygen concentration is required to be not less than 30%. If the volume fraction is less than 30%, SiO₂ particles are dropped off during the polishing.

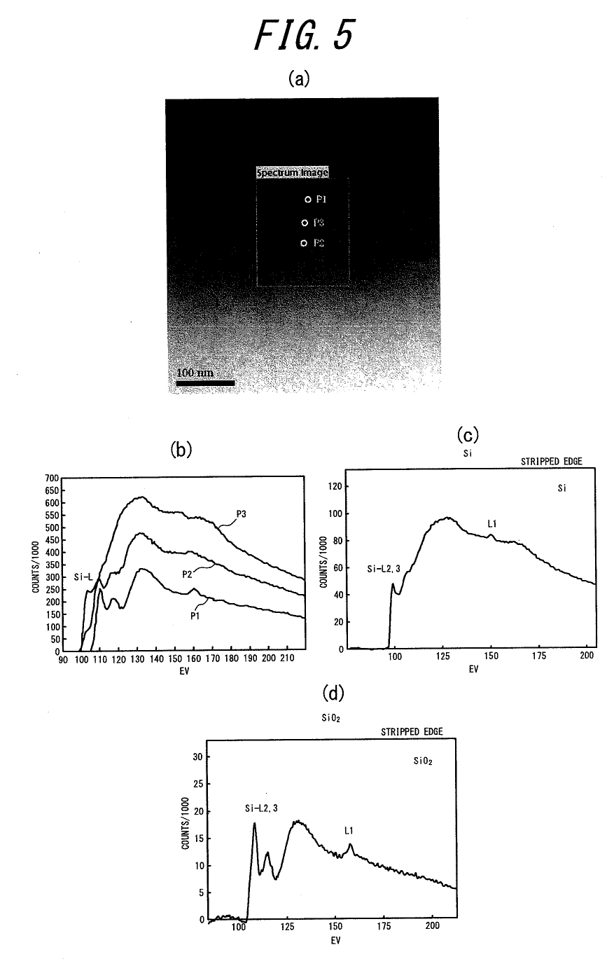

FIG. 5(a) shows a result of analyzing a structure of an oxygen ion implanted layer (stop layer) after polishing stop in the bonded wafer of the above Example as to the same portion as in FIG. 4(a) by means of an electron energy loss spectroscopy (EELS). FIG. 5(b) shows spectrums for three points P1, P2 and P3 in this order from a surface side within a framed area of the oxygen ion implanted layer in FIG. 5(a). FIGS. 5(c) and 5(d) show typical spectrums of Si and SiO₂ in textbooks. Thus, it is seen that SiO₂ clearly exists at an outermost point P1 in the white portion of FIG. 4(c) and Si clearly exists at an innermost point P3 and a middle point P2 in a white portion and a grey portion of FIG. 4(b).

In the method of producing a bonded wafer according to the invention, it is made possible to provide an oxygen ion implanted layer having a sufficiently high polishing stop function desirable as a polishing stop layer and capable of cheaply implanting oxygen ions during the production of the bonded wafer, so that there can be cheaply produced a bonded wafer being excellent in the thickness uniformity of the active layer.

What is claimed is:

1. A method of producing a bonded wafer by bonding a wafer for active layer to a wafer for support layer, which comprises a series of steps including:
(1) a step of implanting oxygen ions into the wafer for active layer to form an oxygen ion implanted layer;
(2) a step of bonding the oxygen ion implanted surface of the wafer for active layer to the wafer for support layer directly or through an insulating film;
(3) a step of conducting a heat treatment for increasing a bonding strength of the bonded wafer,
(4) a step of thinning a portion of the wafer for active layer in the bonded wafer to expose the oxygen ion implanted layer; and
(5) a step of removing the oxygen ion implanted layer from the wafer for active layer in the bonded wafer, wherein
a volume fraction of SiO₂ particles dispersed into silicon in the oxygen ion implanted layer formed at the step (1) of implanting oxygen ions into the wafer for active layer or at the above implantation step and subsequent heat treatment step is set to not less than 30% but not more than 80%; and
at the step (4) of thinning the portion of the wafer for active layer, the oxygen ion implanted layer formed in the step (1) of implanting oxygen ions into the wafer for active layer is used as a polishing stop layer to polish at least the portion of the wafer for active layer.

2. A method of producing a bonded wafer according to claim 1, wherein at the step (1) of implanting oxygen ions into the wafer for active layer, oxygen ions are implanted so that a first differential value of average oxygen concentration distribution directing from the implanted surface side in oxygen ion implanted layer toward an inside thereof is positive.

3. A method of producing a bonded wafer according to claim 1, wherein the step (5) of removing the oxygen ion implanted layer is further followed by (6) a step of planarizing and/or thinning the surface of the wafer for active layer in the bonded wafer.

4. A method of producing a bonded wafer according to claim 2, wherein the step (5) of removing the oxygen ion implanted layer is further followed by (6) a step of planarizing and/or thinning the surface of the wafer for active layer in the bonded wafer.
